(19) United States
(12) Patent Application Publication
(10) Pub. No.: US 2009/0141554 A1
(43) Pub. Date: Jun. 4, 2009

(54) MEMORY DEVICE HAVING SMALL ARRAY AREA

(75) Inventor: Bohumil Lojek, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/030,472

(22) Filed: Feb. 13, 2008

Related U.S. Application Data
(60) Provisional application No. 60/991,680, filed on Nov. 30, 2007.

(51) Int. Cl. G11C 16/04; H01L 21/82

(52) U.S. Cl. 365/185.05; 438/128; 365/185.18; 257/E21.602

(57) ABSTRACT

Memory arrays can be implemented including word lines connected to memory transistors and corresponding select transistors. Each memory transistor is also connected to an array select transistor. Each select transistor is also connected to a bit line. The memory transistors are arranged such that they define bytes of data. A well line is connected to each portion of the semiconductor substrate that defines an array of bytes.

### RELATED APPLICATION

This application claims a benefit of priority from U.S. Provisional Patent Application No. 60/991,680, titled “Memory Device Having Small Array Area,” filed Nov. 30, 2007, which is incorporated by reference herein in its entirety.

### TECHNICAL FIELD

This document relates generally to the field of memory devices.

### BACKGROUND

Several types of nonvolatile memory cells have been used in commercial products, including EPROM, EEPROM, and flash memory types. An example semiconductor memory array can include a matrix of rows and columns of electrical conducting paths formed on a semiconductor chip. The conducting paths of the matrix do not physically intersect but rather are interconnected at the cross-over points by memory cells. Each memory cell can store a bit of binary data, i.e., either a “0” or a “1”. Whether a “0” or a “1” is stored is based upon whether or not the cell conducts.

Binary data stored in the memory array can be read from an individual memory cell by applying a voltage to the conducting row containing the selected cell. The conducting column of that selected cell can then be monitored to determine whether it is drawing current. Nonvolatile memory types typically employ a byte select transistor to select the conducting row that stores the binary values to be read, which increase the footprint of a memory array. An individual row typically stores a collection of bit values that represent a word, and a word can contain 8, 16, 32, 64, or some other number of bits.

### SUMMARY

Disclosed herein are memory arrays, devices, and methods. In general, one aspect of the subject matter described in this specification can be embodied in memory arrays that include word lines connected to memory transistors and corresponding bit select transistors, where each memory transistor is also connected to an array select transistor. Each bit select transistor is also connected to a bit line. The memory transistors are arranged such that they define bytes of data. A well line is connected to each portion of the semiconductor substrate that defines an array of bytes.

Implementations may include one or more of the following features and/or advantages. The memory arrays are byte selectable, thereby allowing each byte to be individually selectable for reading, writing, and erasing the bits. A more dense memory array can also be achieved because a byte select transistor is not required between each group of memory transistors that define a byte. Other features and advantages of the invention will be apparent from the description, drawings, and the claims.

### DESCRIPTION OF DRAWINGS

FIG. 1 is a circuit diagram of an example memory device.

FIG. 2 is a partial cross-section view of an example memory device.

FIG. 3 shows a partial schematic of an example memory device in write mode.

FIG. 4 shows a partial schematic of an example memory device in erase mode.

FIG. 5 shows a partial schematic of an example memory device in read mode.

FIG. 6 is a flow diagram of an example process of manufacturing a byte selectable memory device.

Like reference symbols in the various drawings indicate like elements.

### DETAILED DESCRIPTION

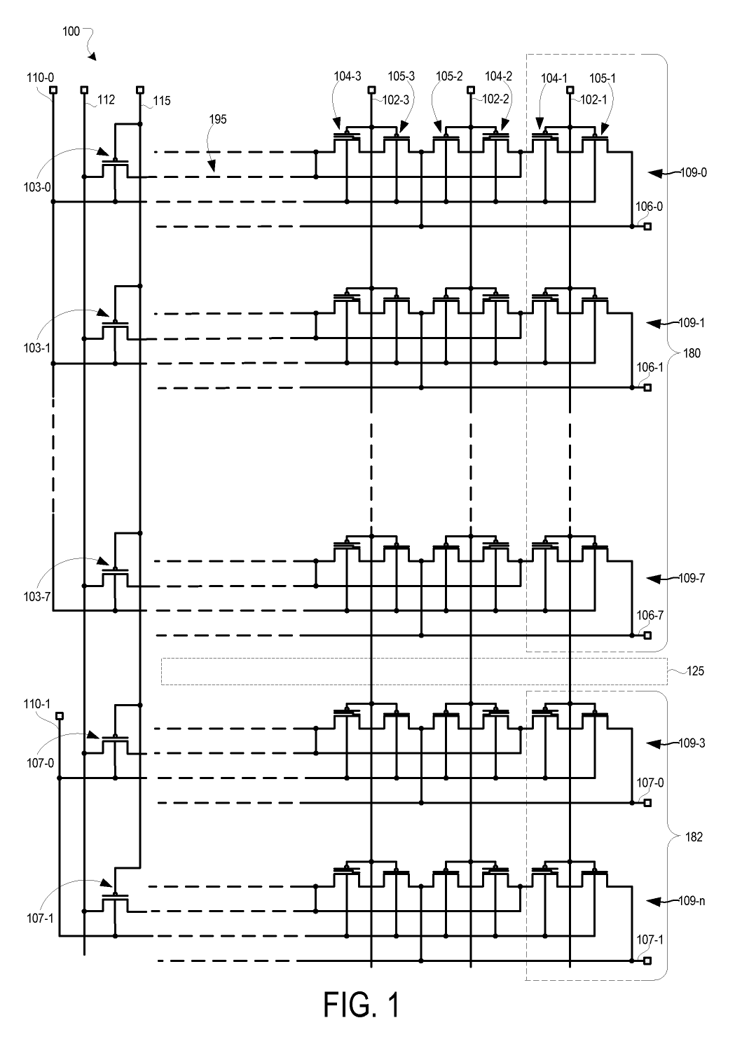

FIG. 1 shows a partial schematic of an example memory device 100. The memory device 100 can represent a nonvolatile circuit memory circuit. The example memory device 100 can include n word lines 102, of which the first three word lines 102-1, 102-2 and 102-3 are shown. The word lines 102 represent groups of bits (e.g., words). The word lines 102 are arranged according to a matrix architecture, e.g., in parallel. Each word line 102 is respectively connected to a corresponding gate of a memory transistor 104, of which the first three memory transistors 104-1, 104-2 and 104-3 are shown. Each word line 102 is also respectively connected to a corresponding gate of a bit select transistor 105, of which the first three bit select transistors 105-1, 105-2 and 105-3 are shown. In some implementations the memory transistors 104 and/or bit select transistors 105 can be MOSFET floating gate structures. When a floating gate structure is used for the bit select transistor 105, the control gate and the floating gate are connected so that the bit select transistor 105 operates as a single gate transistor.

Utilizing the same gate structure for both the memory transistors 104 and the bit select transistors 105 allows the memory device 100 to have higher device density. Additionally, using a floating gate structure for the memory transistors 104 and bit select transistors 105 allows transistor gates to be fabricated utilizing only one mask. Other types of select transistors, however, can also be used.

A bit line 106-0 is connected to the bit select transistors 105-1, 105-2, 105-3. Each bit line 106 is respectively connected to a corresponding drain of a bit select transistor 105. Each bit select transistor 105, in turn, is connected to a corresponding memory transistor 104. As shown in FIG. 1, the memory transistors 104 and the bit selector transistors 105 are adjacently connected, e.g., the sources of respective memory transistors 104 are connected, and the drains of respective bit select transistors 105 are connected. The sources of each bit select transistor 105 are connected to the drains of corresponding memory transistors 104. The numbering of every memory transistor and bit select transistor is omitted to avoid congestion in the FIG. 1. When configured in this manner, the memory transistors 104 that are connected to a common word line 102 may be programmed simultaneously, resulting in a row addressable memory array.

The example memory device 100 also includes Nwell lines 110, a byte select source line 112, and a byte select gate line 115. The lines 110, 112, 115 are arranged according to the matrix architecture, e.g., in parallel and in substantially the same orientation as the word lines 102. The memory device 100 further includes array select transistors 103. The gate of each array select transistor 103 is connected to the byte select gate line 115. The drain of the array select transistor 103 is connected to a respective source of a memory transistor 104 by a line 195. The source of each array select transistor 103 is connected to the byte source select line 112. Additionally, each array select transistor 103 includes a well connection that is connected to the well connection of the memory transistors 104 and bit select transistors 105 and an Nwell line 110.

The memory device 100 includes arrays 109-0, 109-1, . . . , 109-n of memory bits corresponding to each bit line 106 and array select transistor 103, where each array 109 can include a very large number of memory bits. An illustrative byte 180 can include eight (8) bits on eight respective arrays; thus, each array can include memory bits corresponding to a large number of bytes.

The architecture of the device 100 permits the elimination of byte select transistors in an area 125 between respective bytes. Instead, particular memory bits are addressed (i.e., selected) by biasing the Nwell line 110 and through the use of the array select transistor 103, word lines 102, and bit lines 109. Because each array select transistor 103 is located adjacent a large number of memory bits included in an array 109 there is very little space between each memory byte. This results in a reduction in size of the memory device 100 over prior art devices due to the reduction in space of memory array overhead (e.g., overhead including the use of byte select transistors). The actual memory area of the memory device 100 is relatively small compared to the memory area of the device 100 as estimated based on the product of the memory cell area and the memory density. The use of this device 100 architecture can also reduce the maximum voltage required for operation of the device 100.

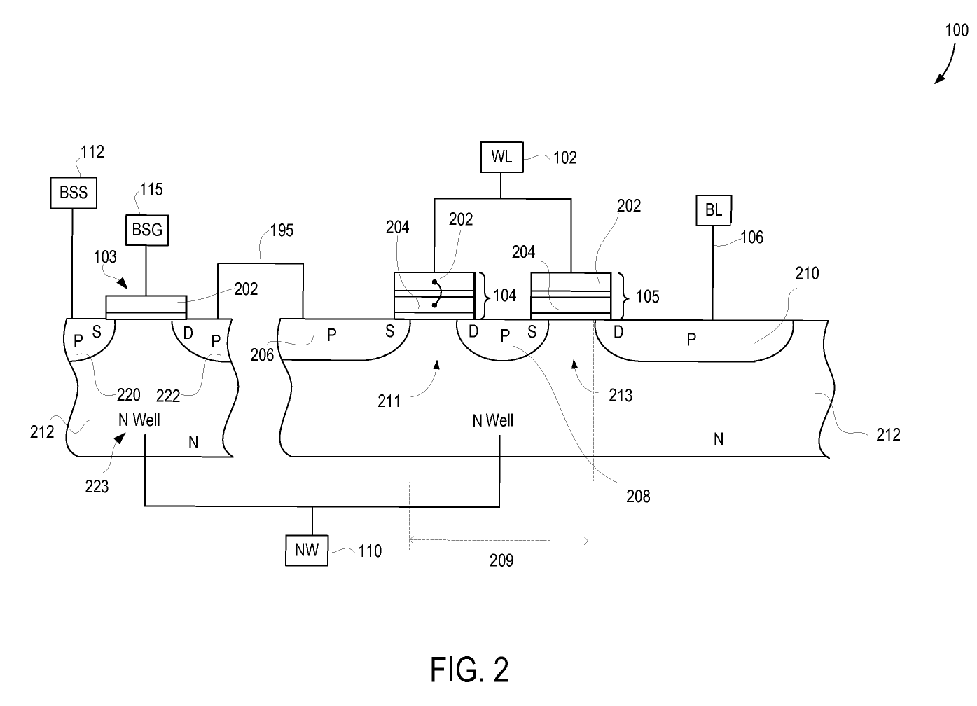

FIG. 2 is a cross-section view of a portion of the memory device 100. The device 100 includes two floating gate MOSFET structures corresponding to a memory transistor 104 and a bit select transistor 105, each including a control gate 202 and a floating gate 204. The device 100 also include P regions 206, 208, 210, 220, 222 forming the sources and the drains of the MOSFET structures, and a body 212. The floating gate 204 and the control gate 202 for the bit select transistor 105 are connected so that the bit select transistor 105 can operate as a single gate transistor. Additionally, a single gate MOSFET structure corresponding to an array select transistor 103 is shown having a control gate 202 and P regions 220, 222 defining a source and drain.

A word line 102 is connected to the control gate 202 of the memory transistor 104 and the bit select transistor 105. A bit line 106 is connected to the P+ region 210 defining the drain of the bit select transistor 105. Additionally, a byte select gate line 115 is connected to the control gate 202 of the array select transistor 103, and the byte select source line 112 is connected to the P+ region 220 defining the source of the array select transistor 103. The P+ region 222 defining the drain of the array select transistor 103 is connected via line 195 to the P+ region 206 defining the source of the memory transistor 104.

According to some implementations, the memory transistor 104 and the bit select transistor 105 can be fabricated as floating gate transistors to enable manufacturing to be performed with only one gate mask, thereby simplifying the manufacturing process, although this is not required. The drain of the bit select transistor 105 is formed by P+ region 210, and the body 212 is shown as an N region. A first Nwell region 209 is formed by the area within the body 212 below the P+ region 208 common to the bit select transistor 105 and the memory transistor 104. A second Nwell 223 region is formed by the area within the body 212 under the array select transistor 103. The first and second Nwell regions are connected to the Nwell line 1 10.

The gates 202 and 204 of the device may be constructed of polysilicon or other appropriate conductive gate material. The P regions 206, 208 and 210 may be formed in any appropriate semiconductor material, for example, silicon or any appropriate semiconductor material, and can be created by introducing dopants into regions of the silicon and activating these dopants through an annealing process. However, during this annealing process, the high temperatures utilized to activate the P+ dopants will cause the dopants to redistribute by diffusing through the body 212 creating larger P doped regions 206, 208, 210, 220 and 222.

The following paragraphs describe the operation of the memory array to write, read, and erase the memory transistors 104. A write operation describes an operational scenario where electrons are forced onto the floating gate 204 of the memory transistor 104. Correspondingly, an erase operation describes an operational scenario where electrons are forced off of the floating gate 204 of the memory transistor 104. A read operation describes an operational scenario where the array is biased so that the current flow from the memory transistor 104 can be detected.

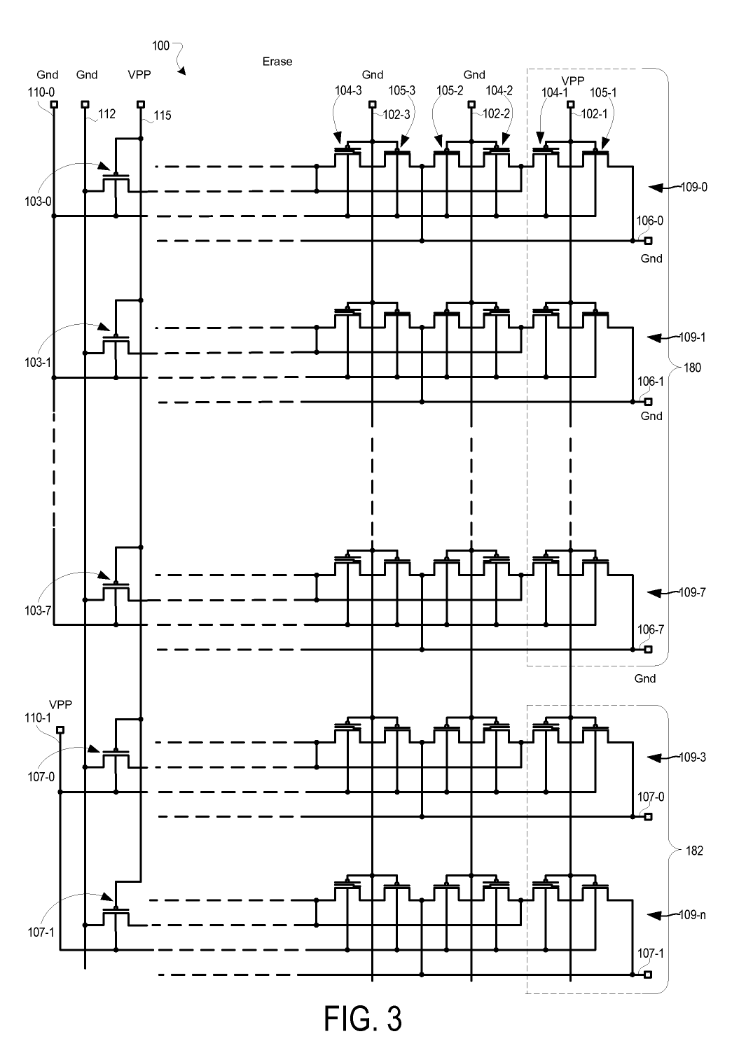

FIG. 3 shows a partial schematic of an example memory array 100 in erase mode. When the voltages (Gnds and VPPs) shown are applied to the circuit all of the bits 109-0 to 109-7 are all erased. Only the bits that are located in a selected byte 180 will be erased, while the bits that are located in a unselected byte 182 will not be erased. To erase the selected byte 180, the Nwell 110-0 of the selected byte 180 and the bit lines 106-0 to 106-7 are connected to a reference voltage (e.g., ground). Additionally, the word line 102-1 is connected to a voltage VPP. The voltage VPP forces electrons off of the floating gate 204 of the memory transistors 104-1 that are connected to word line 102-1 to the Nwell 110-0.

Memory transistors 104 connected to other word lines, (e.g., connected to word lines 102-2, 102-3, etc.) can be biased to prevent erasing these memory transistors 104. To prevent erasing on these word lines, a reference voltage (e.g., ground) is applied to the corresponding word line. For example, as shown in FIG. 3, the word lines 102-2 to 102-3 are connected to ground. Therefore, the memory transistors connected to these word lines will not be erased and, therefore, will maintain the charge on their respective floating gates.

Similarly, memory transistors in the unselected byte 182 will not be erased during the process described above. The Nwell 110-1 of the unselected byte is connected to a voltage VPP. Even the memory transistors 104 that are connected to the word line 102-1 will not be written because the voltage VPP applied to the control gate of the memory transistor 104 is the same voltage VPP applied to the corresponding Nwell 110-1. Therefore, the voltage difference between the control gate and the Nwell 110-1 will be negligible and, in turn, will not force electrons from the floating gate to the Nwell 110-1.

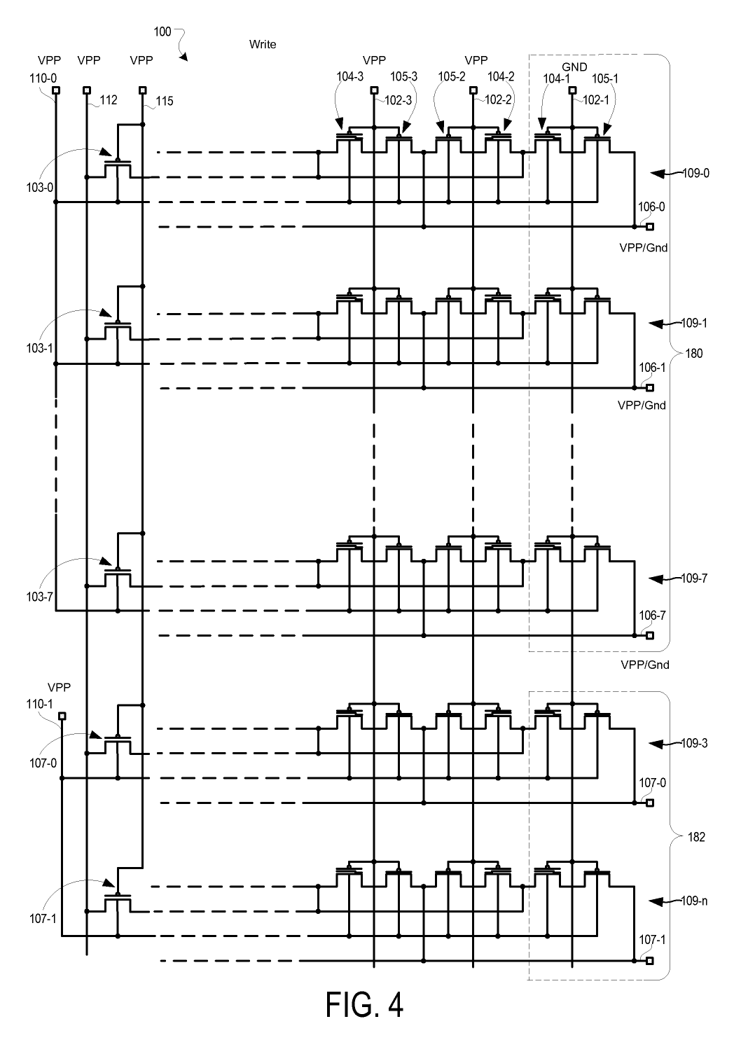

FIG. 4 shows a partial schematic of an example memory array 100 in write mode. When the voltages (Gnds, VPPs, VPP/Gnd) shown are applied to the circuit the memory transistors 104 that are in the selected byte 180 can be selectively written. The Nwell 110-0 for the selected byte 180 has the voltage VPP applied to it. Additionally, biasing voltages are applied to the word lines 102-1, 102-2, 102-3, etc. that determine which byte of memory transistors are biased for writing. The array select transistors 103-0-103-7 are also connected to biasing voltages that enable programming of the memory transistors 104 in the selected byte 180. Each of the memory transistors 104 in the selected byte 180 can be selectively written according to the voltage applied to a corresponding bit line 109-0 to 109-7.

In order for a memory transistor 104 to be selectively erasable, a reference voltage (e.g., ground) is applied to the corresponding word line because the Nwell has a voltage VPP applied to it. Additionally, a voltage VPP must be applied to the byte select gate 115 and the byte select source line 112 of the array select transistors 103-0 to 103-7. Conversely, applying a voltage VPP to a word line will prevent the memory transistors connected to that word line from being written.

For example, in FIG. 4 word line 102-1 is connected to ground. The byte select gate 115 and byte select source 112 associated with the array select transistors 103-0 - 103-7 are each connected to the voltage VPP. Therefore, any of the memory transistors in the selected byte 180 that are connected to word line 102-1 can be selectively written by applying either ground or VPP to the bit lines 106-0 to 106-7.

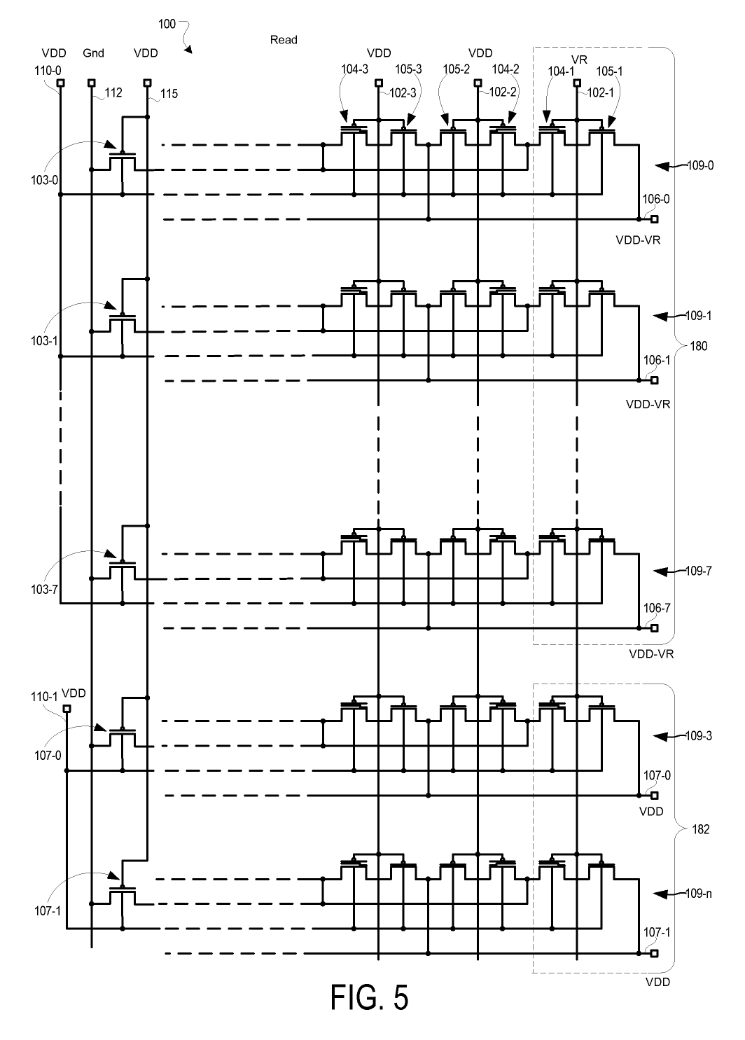

FIG. 5 shows a partial schematic of an example memory array 100 in read mode. When the voltages (VDD, Gnd, VR, VDD-VR) shown are applied to the circuit, the current of the memory transistors in the selected byte 180 can be detected to determine whether the memory transistors are at logic state “1” or logic state “0.” A read voltage VR is applied to the word line 102-1 that is connected to the memory transistors that are to be read. Additionally, a biasing voltage of VDD is applied to the byte select gate 115 of the array select transistors 103-0, 103-7, while a reference voltage (e.g., ground) is applied to the byte source select line 1 12. A voltage VDD-VR is applied to the bit lines 109-0 to 109-7. These voltages bias the transistors so that current will flow from the memory transistors that are in the selected byte 180 and connected to the word line 102-1. This current is detected and compared to a threshold current. Based on this comparison, the memory transistor is identified as having a logic state of either “1” or “0.”

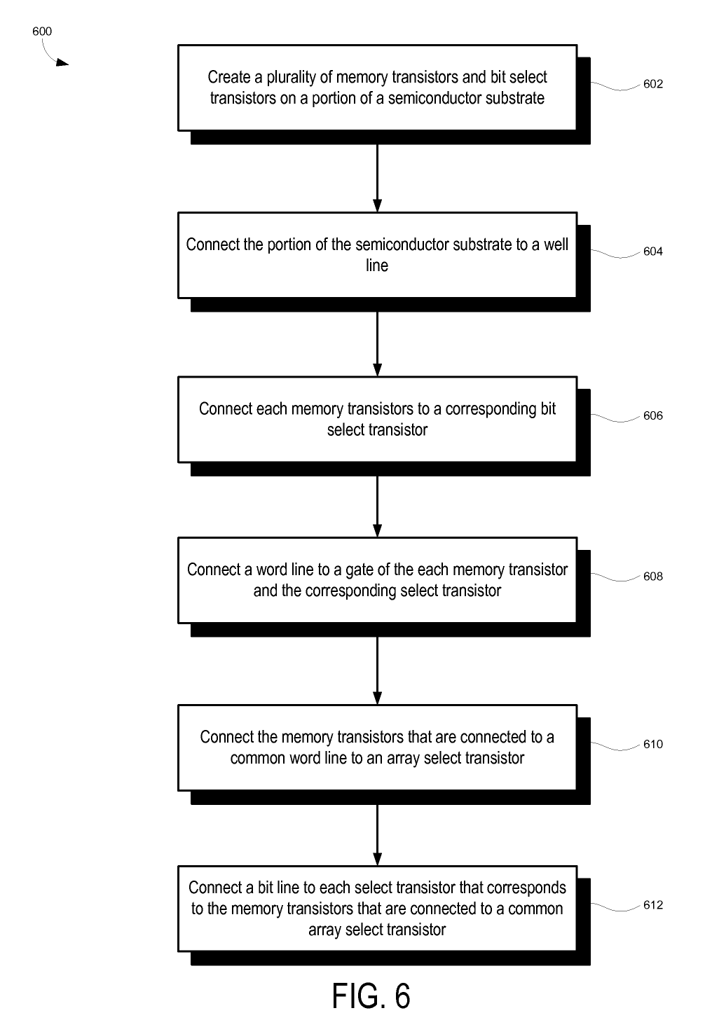

FIG. 6 is a flow diagram of an example process 600 of manufacturing a byte selectable memory device. The process begins by creating a plurality of memory transistors and bit select transistors on a portion of a semiconductor substrate (602). The memory transistor gates and bit select gates can both be formed from a floating poly line and a control poly line. The bit select gates can have the floating poly line and the control poly line connected so that the bit select gates function as a single gate.

The process 600 continues by connecting the portion of the semiconductor substrate to a well line (604). The semiconductor substrate can be connected to the well line through a connection pad located in the substrate. The well line can be used to bias the body of the substrate.

Next, the process 600 connects each of the plurality of memory transistors to a corresponding bit select transistor (606). The memory transistors can have their drain connected to the source of the bit select transistors. In some implementations, the memory transistor and corresponding bit select transistor can have their respective drain and source defined by a common doped region in the semiconductor substrate.

The process 600 continues by connecting a word line to a gate of the each memory transistor and the corresponding select transistor (608). The word line is connected, for example, to the control gates 202 of the memory transistor 104 and the select transistor.105.

The process 600 continues by connecting the memory transistors that are connected to a common word line to an array select transistor (610). For, example, each memory transistor 104 on a common word line 102 can have its source connected to the drain of the corresponding array select transistor 103.

Next, the process 600 connects a bit line to each select transistor that corresponds to the memory transistors that are connected to a common array select transistor (612). For example, all of the select transistors 105 that are connected to memory transistors 104 that are connected to the array transistor 103-0 can have their drains connected to the common bit line 109-0.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

1. A memory device, comprising:
a plurality of selectable arrays, each selectable array comprising:
a bit line;
a plurality of word lines;
a plurality of transistor pairs connected to the bit line, wherein each transistor pair in the plurality of transistor pairs is connected to a respective word line of the plurality of word lines;
an array select transistor connected to each of the plurality of transistor pairs, the array select transistor having a source; and
a well line connected to each of the plurality of transistor pairs and to the array transistor,
wherein the sources of the array select transistors in the plurality of selectable arrays are connected.

2. The memory device of claim 1, wherein each array select transistor is operable to address a particular byte.

3. The memory device of claim 1, wherein each transistor pair comprises a select transistor and a memory transistor.

4. The memory device of claim 1, wherein a gate of the select transistor and a gate of the memory transistor in each transistor pair are connected to a respective word line of the plurality of word lines.

5. The memory device of claim 4, wherein the bit line is connected to a drain of each select transistor in the selectable array including the bit line.

6. The memory device of claim 5, wherein a drain of the array select transistor is connected to a source of each memory transistor in the plurality of transistor pairs connected to the bit line.

7. The memory device of claim 3, wherein the memory transistor comprises a floating gate transistor.

8. The memory device of claim 3, wherein the select transistor comprises a floating gate connected to a control gate.

9. The memory device of claim 1, wherein the well line is connected to a biasing source for selectively biasing a well region during operation of the memory device.

10. The memory device of claim 5, wherein operation of the memory device comprises at least one of read, write, and erase operations.

11. A memory array, comprising:
a plurality of word lines;
a plurality of memory transistors connected to each word line;
a plurality of select transistors, each select transistor connected to a corresponding memory transistor, and having a gate connected to the word line that is connected to the corresponding memory transistor;
a plurality of bit lines, each bit line connected to a drain of the select transistors that are connected to a common word line;
a plurality of array transistors, each array transistor connected to the memory transistors that are connected to the select transistors that are connected to a common bit line; and
a well line connected to a well of each memory transistor that is connected to a common word line and defines a byte.

12. The memory array of claim 11, wherein the plurality of memory transistors are floating gate transistors.

13. The memory array of claim 11, wherein an array of bytes are connected to a common well line.

14. The memory array of claim 11, wherein the plurality of select transistors have a floating gate that is connected to a control gate.

15. The memory array of claim 11, wherein the well line is connected to a biasing source for selectively biasing a well region during operation of the memory array.

16. The memory array of claim 15, wherein operation is comprised of read, write, and erase operations.

17. A method, comprising:
creating a plurality of memory transistors and bit selector transistors on a portion of a semiconductor substrate;
connecting the portion of the semiconductor substrate to a well line, each portion of the semiconductor substrate containing memory transistors that define a byte array and have a common well;
connecting each memory transistors to a corresponding bit select transistor;
connecting a word line to a gate of the each memory transistor and the corresponding select transistor;
connecting the memory transistors that are connected to a common word line to an array select transistor; and
connecting a bit line to each select transistor that corresponds to the memory transistors that are connected to a common array select transistor.

18. The method of claim 17, wherein memory transistors that define a byte of memory are connected to a common word line and located over a common well.

19. The method of claim 18, wherein bytes of memory located on different word lines are located over a common well.

20. A memory array comprising:
an array of memory transistors;
an array of select transistors, each select transistor connected to a corresponding memory transistor in the array of memory transistors;
a word line connected to a gate of each select transistor and the corresponding memory transistor;
an array select transistor connected to a drain of one memory transistor from the word line;
a well line connected to the well of each select transistor and the corresponding memory transistor that define a byte of data;
a bit line connected to one select transistor from each word line.
